(19) United States
(12) Patent Application Publication
(10) Pub. No.: US 2024/0215176 A1
(43) Pub. Date: Jun. 27, 2024

(54) ICE MAKING DEVICE

(71) Applicant: NIDEC INSTRUMENTS CORPORATION, Nagano (JP)

(72) Inventor: Yuta OSHIMA, Nagano (JP)

(73) Assignee: NIDEC INSTRUMENTS CORPORATION, Nagano (JP)

(21) Appl. No.: 18/395,742

(22) Filed: Dec. 26, 2023

(30) Foreign Application Priority Data
Dec. 27, 2022 (JP) 2022-210304

(51) Int. Cl. H05K 5/00; F25C 1/24

(52) U.S. Cl. CPC H05K 5/0026; F25C 1/24; F25C 5/06; F25C 2400/10; F25C 2600/04

(57) ABSTRACT

An ice making device includes an ice making tray, an outer shell case which is a case body structuring an outer shape of the device, and a board case which accommodates a circuit board. The board case is disposed in an inside of the outer shell case.

### CROSS REFERENCE TO RELATED APPLICATION

The present invention claims priority under 35 U.S.C. § 119 to Japanese Application No. 2022-210304 filed Dec. 27, 2022, the entire content of which is incorporated herein by reference.

### TECHNICAL FIELD

At least an embodiment of the present invention may relate to an ice making device and, more specifically, relate to an automatic ice making device including a control part.

### BACKGROUND

In Japanese Patent Laid-Open No. 2019-45043, an automatic ice making device is disclosed which includes a first circuit board having an AC/DC converter and a second circuit board for control.

An ice making device which automatically performs a series of ice making operations includes a circuit board for controlling electric power and signals. In a case that an operator assembles a circuit board by soldering, connection quality of the circuit board may be varied depending on a skill of soldering work. Further, safety such as an insulation property and an explosion-proof property is required in a circuit (high power circuit) for handling electricity as power, and naturally, it is also required that assembling quality and connection quality are satisfactory.

### SUMMARY

At least an embodiment of the present invention may advantageously provide an ice making device in which assemblability and safety are improved.

According to at least an embodiment of the present invention, there may be provided an ice making device having an ice making tray, an outer shell case which is a case body structuring an outer shape of the device, and a board case which accommodates a circuit board, and the board case is disposed in an inside of the outer shell case. A circuit board is accommodated in a board case, and the board case is assembled in an inside of an outer shell case with the board case as a unit and thereby, handling of the circuit board is easily performed. Further, an insulation property and an explosion-proof property of the circuit board can be also secured by the board case, and safety of the device can be flexibly secured.

In this case, the circuit board includes a terminal which electrically connects the circuit board with another component, the board case is provided with a terminal port which is an opening for exposing the terminal outside, the terminal is a male terminal or a female terminal which is capable of being inserted to and removed from a connection part of the another component, an inside of the outer shell case is provided with a case disposing part to which the board case is attached, and the terminal of the circuit board is connected with the connection part of the another component by attaching the board case to the case disposing part. According to this structure, the terminal of the circuit board is connected with another component in a structure capable of being inserted and removed (i.e., connector connection) instead of soldering and thus, assembling of the circuit board can be easily performed and constant connection quality can be obtained regardless of skill of soldering work.

Further, the ice making device in accordance with the present invention may be structured that the board case and the case disposing part are respectively provided with slide fitting parts, the slide fitting parts are fitted to each other by sliding the board case on the case disposing part in an insertion direction of the terminal, and the board case is prevented from moving except an inserting and removing direction of the terminal. Insertion of the terminal and fixing of the board case are simultaneously completed only by sliding the board case and thus, assemblability of the ice making device is enhanced.

Further, the ice making device in accordance with the present invention may be structured that the case disposing part is provided with a stopper part, and the stopper part is abutted with the board case when the board case is slid on the case disposing part in an insertion direction of the terminal to determine a moving limit of the board case in the insertion direction. When a final position of the board case after being slid is determined by the stopper part, an insertion state of the terminal is made uniform and connection quality of the circuit board is stabilized.

Further, the ice making device in accordance with the present invention may be structured that the board case and the case disposing part are respectively provided with snap-fit structures, and the snap-fit structures are fitted to each other by sliding the board case on the case disposing part in the insertion direction of the terminal. Insertion of the terminal and fixing of the board case are simultaneously completed only by sliding the board case and thus, assemblability of the ice making device is enhanced. In addition, a predetermined amount of insertion of the terminal is transmitted to an operator through a fitting sound and a feeling of snap fitting and thus, an insertion state of the terminal is made uniform and connection quality of the circuit board is stabilized.

Further, the ice making device in accordance with the present invention may be structured that the outer shell case includes a cover part which is capable of being attached and detached, an inner face of the cover part is contacted with an opposing face which is an outer face of the board case, and the inner face of the cover part is formed with a recessed part whose shape is the same as a shape of the opposing face of the board case with which the cover part is contacted, or formed with a rib which is fitted to a periphery of the opposing face of the board case. When the board case disposed on the case disposing part is fixed in an unmovable state by the cover part, the board case and the circuit board can be firmly fixed at a predetermined position. Further, when the recessed part or the rib of the cover part is not properly fitted to the opposing face of the board case, an operator is capable of recognizing insufficient insertion of the terminal. In this case, it may be structured that the inner face of the cover part and the opposing face of the board case are provided with a protrusion and a recess whose shapes are paired, and the protrusion and the recess are fitted to each other by attaching the cover part to the board case. As a result, the effect that the cover part holds a position of the board case is enhanced.

Further, the ice making device in accordance with the present invention may be structured that the case disposing part is provided with an insertion port which is an opening into which the terminal is inserted, a connection part of the another component is disposed on a rear side with respect to the insertion port, and the connection part is invisible in a direction other than the insertion direction of the terminal. When a connection part of another component is visually concealed from an operator, the operator consequently inserts the terminal into the insertion port based on a normal operation procedure. In other words, an operator is prevented from intuitively and easily inserting the terminal to a visible connection part and thus, the operator inserts the terminal in a correct direction determined by the operation procedure.

In this case, the board case may be provided with a terminal housing which surrounds the terminal in a tube shape. When the terminal is surrounded by a terminal housing in a tube shape, an inserting direction of the terminal to a connection part of another component is restricted and thus, forcible connection in an incorrect direction can be prevented beforehand.

Further, it may be structured that the ice making device in accordance with the present invention includes a first board which is the circuit board having a converter which converts an alternating current to a direct current, and a second board which is the another component with which a part operated by the direct current is connected, and the second board includes a control part which controls an operation of the ice making device, and the terminal of the first board is connected with the second board through an inter-board connector which is the connection part. When the first board (circuit board) and the second board (another component) are fittingly connected (structurally connected) by an inter-board connector, connection work of the circuit board is easily performed and its connection quality is made uniform. Further, when the circuit board is divided into a plurality of circuit boards based on types of input currents, functions and the like of parts which are mounted on the circuit board, the respective circuit boards can be flexibly arranged at optimum positions.

In this case, it may be structured that the inter-board connector perpendicularly connects the first board with the second board. When the first board and the second board are perpendicularly connected with each other, a maximum size in a three-dimensional direction after having been connected can be made smaller than a maximum size of the two boards which are connected on the same plane. As a result, the circuit board is prevented from becoming a bottleneck for miniaturization.

Further, in this case, no lead wire is used for connection of the first board with the second board. According to this structure, an arrangement space of a lead wire is eliminated and a size of the ice making device can be further reduced.

Further, in this case, it may be structured that the first board includes a relay which opens and closes a water supply valve for supplying water to the ice making tray. When a relay which commonly has a mechanical contact is mounted on the first board, a problem such as noise and a spark can be gathered to the first board. Further, since the second board controls electric and electronic components by receiving supply of DC power from the first board, the second board is anticipated to be arranged on an inner and back portion of the device with respect to the first board. Therefore, when the relay which is connected with a mechanical element (water supply valve in an embodiment of the present invention) provided outside the device is disposed on the first board instead of the second board, the relay and the water supply valve are easily accessed.

Further, in this case, the first board may include a varistor. When the first board is provided with a detouring function of a surge current, a power supply function of the ice making device is gathered on the first board. As a result, safety of the second board is secured and a configuration of the second board can be made simple.

### EFFECTS OF THE INVENTION

As described above, according to the ice making device in accordance with the present invention, assemblability and safety of the ice making device can be improved.

Other features and advantages of the invention will be apparent from the following detailed description, taken in conjunction with the accompanying drawings that illustrate, by way of example, various features of embodiments of the invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a perspective view showing an outward appearance of an ice making device in accordance with an embodiment of the present invention.

FIGS. 2A, 2B and 2C are schematic views showing a flow of an ice separating operation which is performed by an ice making device.

FIG. 3 is a rear view showing a power transmission path of a drive unit.

FIGS. 4A and 4B are perspective views showing a structure of a case body of an ice making device.

FIG. 5 is a plan transparent view showing arrangement of boards which are provided in a drive unit.

FIG. 6 is a block diagram showing functional configurations of boards.

FIGS. 7A and 7B are perspective views showing an outward appearance of a board case.

FIG. 8 is a perspective view showing a surface structure of an inner case.

FIGS. 9A and 9B are schematic views showing an attaching method of a board case to an inner case.

FIGS. 10A and 10B are schematic cross-sectional views showing a fixing structure of a board case by a cover part.

FIGS. 11A and 11B are perspective views showing a structure of a cam gear.

FIG. 12A is a perspective view showing a structure of a driven shaft and FIG. 12B is its side view.

FIG. 13A is a plan view showing a structure of a switch lever and FIG. 13B is its perspective view.

FIG. 14 is a rear view showing a state of a drive mechanism when an ice making tray is located at an ice making position.

FIG. 15A is a rear view showing a state of a drive mechanism at a time of an ice detection operation and FIG. 15B is its side view.

FIG. 16 is a timing chart showing operations of respective parts when an ice separating operation is continued and interrupted.

FIG. 17 is a rear view showing a state of a drive mechanism at a time of a discharge operation.

FIG. 18 is a rear view showing a state of a drive mechanism after ice pieces have been discharged.

### DETAILED DESCRIPTION

An ice making device in accordance with an embodiment of the present invention will be described below with reference to the accompanying drawings. An ice making device 90 described below is a device which is installed in a freezer chamber of a refrigerator not shown and to which water is supplied from the refrigerator to automatically produce ice pieces.

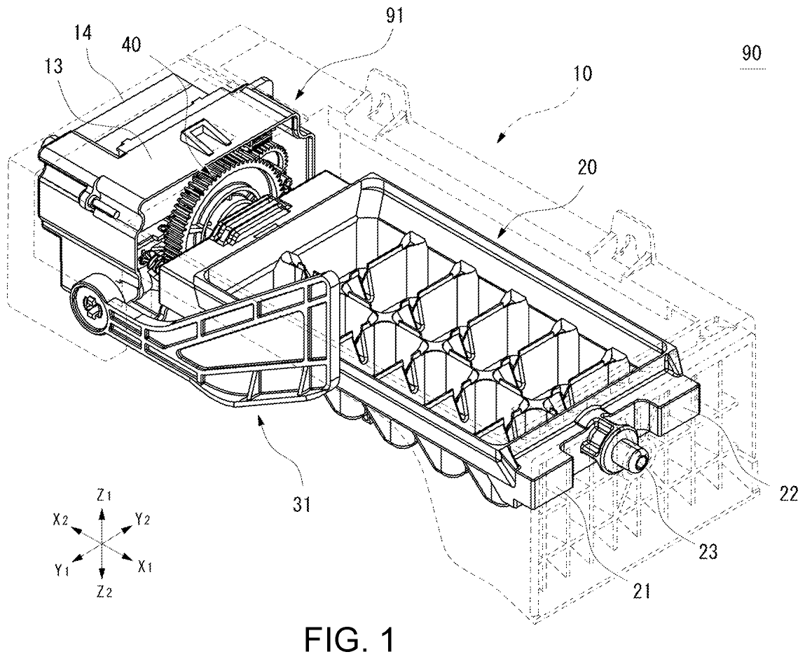

An “upper and lower” direction in the following descriptions is a direction parallel to the “Z”-axis of coordinate axes described in FIG. 1, and the “Z1” side is an “upper” side and the “Z2” side is a “lower” side. A “front and rear” direction is a direction parallel to the “X”-axis of the coordinate axes, and the “X1” side is a “front” side and the “X2” side is a “rear” side. Similarly, a “right and left” direction is a direction parallel to the “Y”-axis of the coordinate axes, and the “Y1” side is a “right” side and the “Y2” side is a “left” side.

### Entire Structure

FIG. 1 is a perspective view showing an outward appearance of an ice making device 90. The ice making device 90 is a so-called twist type ice making device which is structured to discharge ice pieces by twisting an ice making tray 20. The ice making device 90 includes an ice making tray 20 made of resin which is provided with a plurality of cells (water storing compartment) and a drive unit 91 which is a motor unit for turning the ice tray 20. The drive unit 91 and the ice making tray 20 are accommodated and supported by an outer shell case 10 which is a case body installed in an inside of a freezing chamber. Further, the drive unit 91 includes an ice detection lever 31 which is an ice detection member for detecting an amount of ice pieces in an inside of an ice storage part 92 described below.

### Schematic Ice Separating Operation

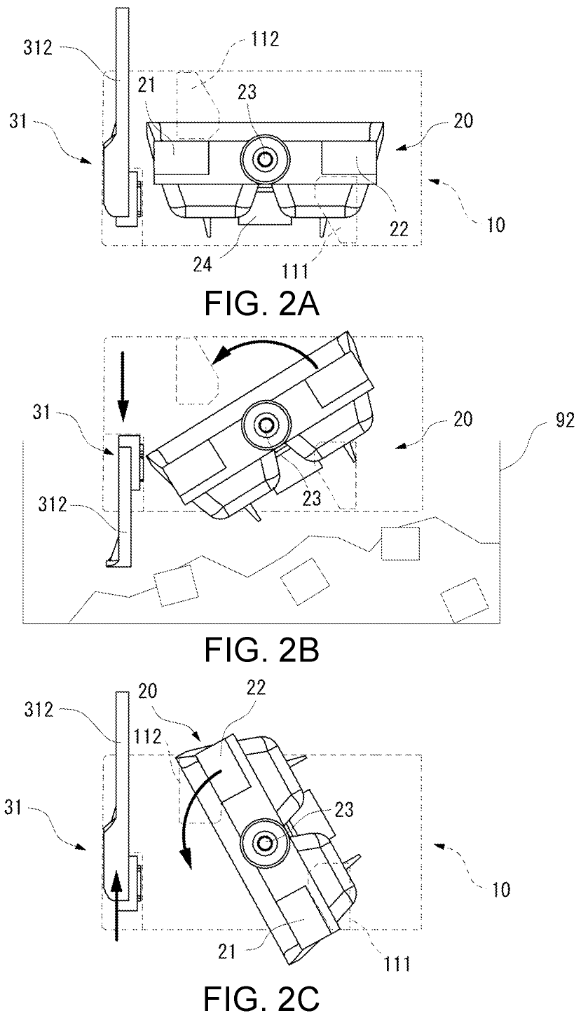

FIGS. 2A, 2B and 2C are schematic views showing a flow of an ice separating operation (operation for discharging ice pieces from the ice tray 20) which is performed by the ice making device 90.

FIG. 2A is a view showing a state that the ice making tray 20 is located at an “ice making position” which is at an arrangement angle where water is held. The ice making device 90 monitors a temperature of the ice making tray 20 by a thermistor 24 which is attached to its lower face and, when it is detected that the temperature of the ice making tray 20 has reached a predetermined value, an ice separating operation is started. FIGS. 2B and 2C are views showing the ice separating operation performed by the ice making device 90.

FIG. 2B is a view showing an “ice detection operation” which is a part of the ice separating operation. The “ice detection operation” is an operation in which an amount of ice pieces within the ice storage part 92 which is a container where ice pieces are stored is measured to determine whether the ice separating operation is continued or interrupted (canceled). When the ice separating operation is started and the ice making tray 20 starts turning in a “CCW” direction in the drawing, an arm part 312 of the ice detection lever 31 is lowered to an inside of the ice storage part 92 interlocking with turning of the ice making tray 20. In this case, when the ice detection lever 31 is moved down lower than a predetermined reference level, it is determined that the amount of the ice pieces is insufficient and thus, the ice separating operation is continued. On the other hand, when the downward movement of the ice detection lever 31 is prevented by stored ice pieces before the ice detection lever 31 reaches the reference level, it is determined that the amount of the ice pieces in the ice storage part 92 is in a full state and the ice separating operation is canceled.

FIG. 2C is a view showing a “discharge operation” which is a part of the ice separating operation. In a case that the amount of the ice pieces in the ice storage part 92 is insufficient, the ice making device 90 continues the ice separating operation. A front end of the ice making tray 20 is formed at its center with a shaft part 23 supported by a shaft hole of the outer shell case 10, and a first protruded part 21 and a second protruded part 22 each of which is a protruded part protruded to a front side are formed on right and left sides with respect to the shaft part 23. The outer shell case 10 is provided with a first contact part 111 and a second contact part 112 for preventing turning of the ice making tray 20 on a turning path of the first protruded part 21 and the second protruded part 22. When the ice making tray 20 is continuously turned in the “CCW” direction in the drawing, the first protruded part 21 and the second protruded part 22 of the ice making tray 20 are contacted with the first contact part 111 and the second contact part 112 of the outer shell case 10. The drive unit 91 further turns the ice making tray 20 from this state by several tens degree in the “CCW” direction to twist the ice making tray 20. As a result, the ice pieces in the ice making tray 20 are discharged to an inside of the ice storage part 92.

### Schematic Drive Mechanism

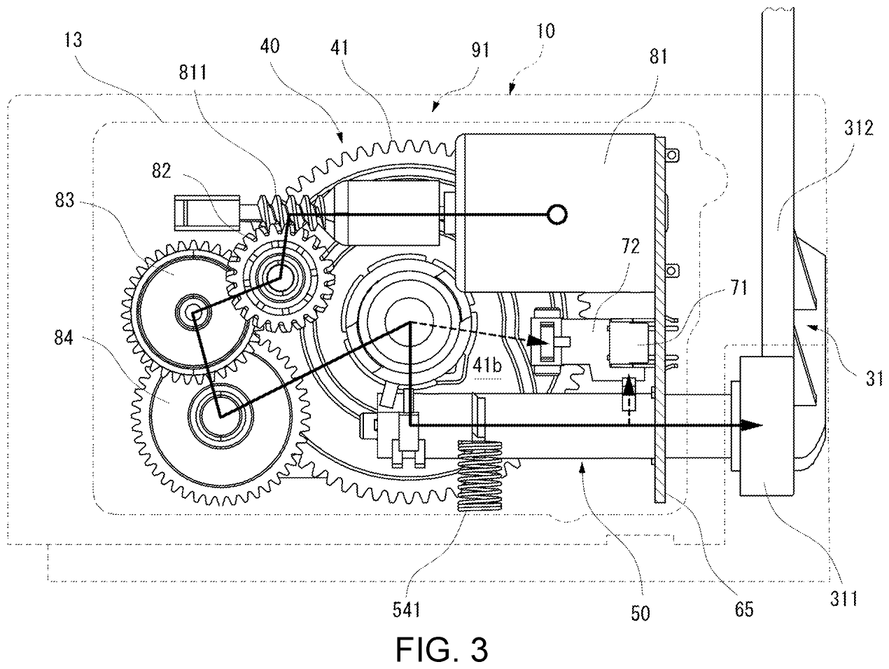

FIG. 3 is a rear view showing a power transmission path of the drive unit 91. The ice making device 90 receives supply of electric power from the refrigerator in which the ice making device 90 is installed to perform various predetermined operations.

The drive unit 91 includes a DC (direct current) motor 81 (hereinafter, simply referred to as a “motor 81”) which is a drive source, a cam gear 40 which is an output part for turning the ice making tray 20, and a driven shaft 50 for moving the ice detection lever 31 up and down interlocking with an operation of the cam gear 40.

The cam gear 40 is provided with a gear part 41 which is a circular plate part in a flange shape enlarged in a circular shape. A rear face 41b of the gear part 41 structures a driver part of a plane cam mechanism. The driven shaft 50 is a shaft body which structures a follower part of the gear part 41. The gear part 41 is formed with a teeth part on its outer peripheral face and functions as a spur gear. Rotation of the motor 81 is decelerated by a speed reduction gear train and is transmitted to the gear part 41 of the cam gear 40. The speed reduction gear train in this embodiment is structured of a worm gear 811 attached to an output shaft of the motor 81, a first gear 82, a second gear 83 and a third gear 84. Each of the first through third gears is a composite gear structured so that a large diameter gear and a small diameter gear are overlapped and integrated with each other in an axial line direction. A large diameter gear of the first gear 82 is a worm wheel which is paired with the worm gear 811.

Further, the rear face 41b of the gear part 41 is also contacted with a switch lever 72 which is another follower part. The switch lever 72 switches “ON” and “OFF” of an ice detection switch 71 which is a mechanical switch according to a turning angle of the cam gear 40 and a turning angle of the driven shaft 50 (in other words, moving-down angle of the ice detection lever 31). The ice making device 90 monitors an output of the ice detection switch 71 and, when an ice quantity in a freezing chamber is sufficient (fully stored state with ice pieces), the ice separating operation performed by the drive unit 91 is canceled and, when the ice quantity is insufficient, the ice separating operation is continued.

### Structure of Case Body

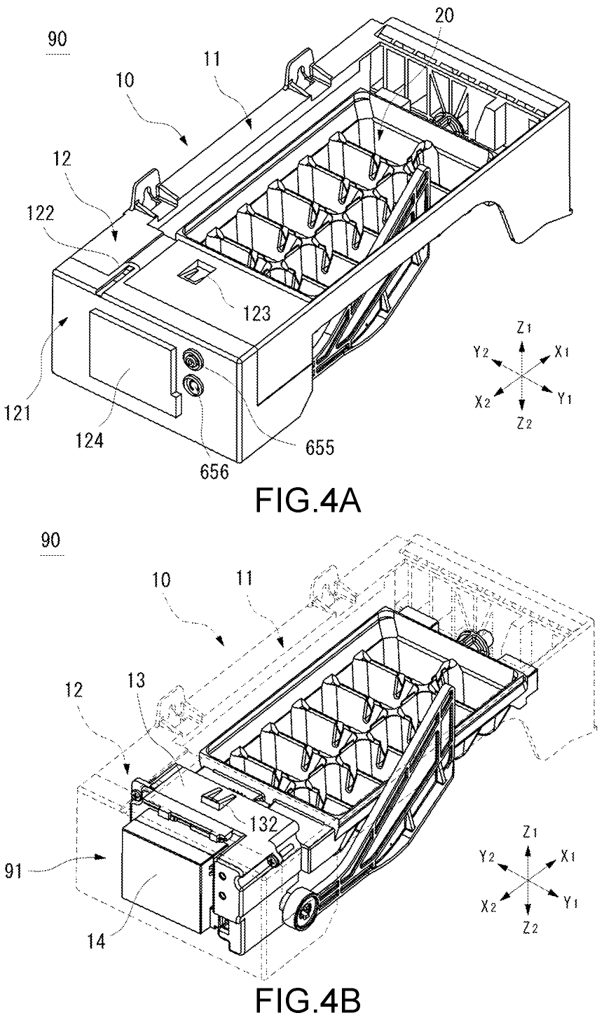

FIGS. 4A and 4B are perspective views showing a structure of the outer shell case 10 of the ice making device 90. The outer shell case 10 is a housing in a substantially rectangular parallelepiped shape as a whole and structures an outer shape of the ice making device 90. The outer shell case 10 turnably supports the ice making tray 20 and accommodates the drive unit 91 in its inside.

The outer shell case 10 is provided with a frame part 11 which holds the ice making tray 20 and a box part 12 which holds the drive unit 91. The frame part 11 is not provided with an upper face and a bottom face which cover the ice making tray 20, and the entire ice making tray 20 is exposed outside. The substantially entire drive unit 91 is covered by the box part 12 except a connection part with the ice making tray 20. The box part 12 has a cover part 121 which is capable of being attached and detached by a hook 122. The hook 122 is also provided in a bottom face of the box part 12 and, when the hooks 122 are disengaged and the cover part 121 is opened, the inside of the box part 12 can be accessed. A rear face (“X2” side end face) of the outer shell case 10, in other words, the cover part 121 is arranged with a main switch 655 which is a button for starting the ice making device 90 and a test switch 656 for confirming an operation of the ice making device 90 by a manufacturer or a service engineer.

An inner case 13 which is a half case body having no cover is fixed to an inner face of the box part 12 by a screw. The inner case 13 is provided with hooks 132 in a protruded shape on its upper face and lower face and, when the hooks 132 are engaged with hole parts 123 provided at corresponding positions in the box part 12, a position of the inner case 13 is temporarily fixed in the box part 12. The inner case 13 is fixed so that its opening is directed toward an inner face on a front side (“X1” side) of the box part 12. The inner case 13 is assembled with mechanical parts such as gears structuring the drive unit 91, a board case 14 described below and the like. In the ice making device 90 in this embodiment, the box part 12 includes the inner case 13 which is a separate member from the box part 12 and thus, the parts structuring the drive unit 91 can be previously assembled in the inner case 13 and they are collectively accommodated and fixed to the box part 12. As a result, assemblability of the ice making device 90 is enhanced.

### Board Configuration

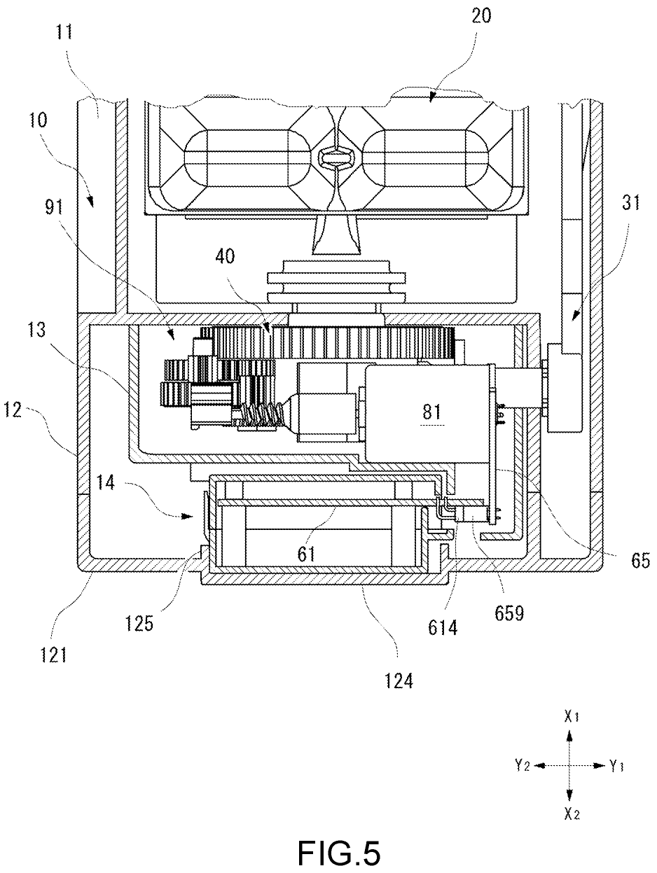

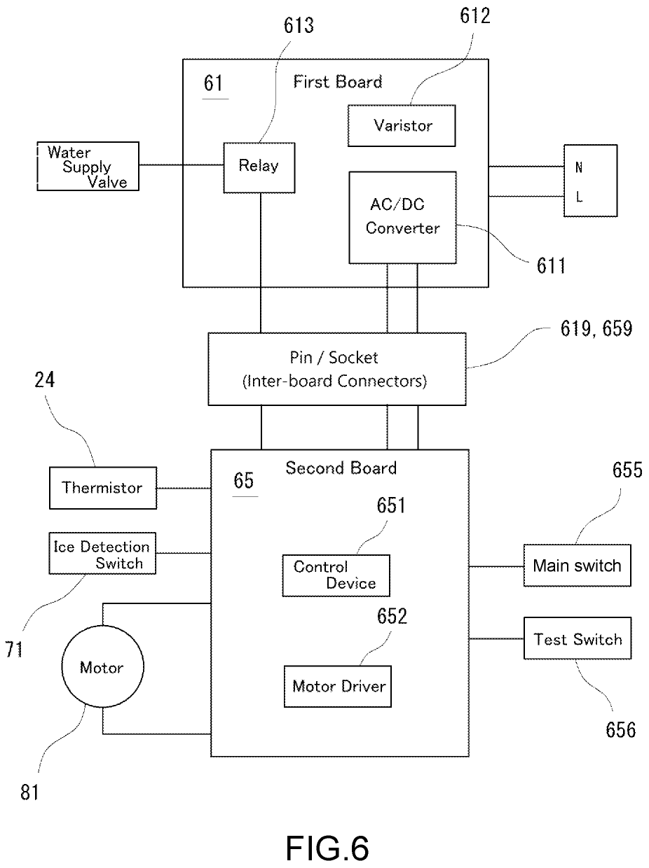

FIG. 5 is a plan transparent view showing arrangement of boards which are provided in the drive unit 91. FIG. 6 is a block diagram showing functional configurations of the boards. A board configuration of the ice making device 90 will be described below with reference to FIGS. 5 and 6.

The ice making device 90 in this embodiment is a full-automatic ice making device which receives supply of electric power from a refrigerator that is a host apparatus to automatically perform water supply, ice making, ice discharging and control of ice storage quantity. Further, the ice making device 90 includes a board for performing conversion of electric power and controlling of various operations.

The board of the ice making device 90 is structured of two rigid boards, i.e., a first board 61 and a second board 65. The first board 61 which is a circuit board is a board provided with an AC/DC converter 611 which is a converter that converts AC power inputted from the refrigerator into DC power. The DC power is supplied from the first board 61 to the second board 65. The second board 65 which is another circuit board is connected with electric and electronic components which are operated by DC power. Further, the second board includes a control device 651 which is a control part for controlling operations of the ice making device 90. The control part is not limited to a specific configuration. The control part in the present invention may be configured so as to be capable of receiving inputs from a sensor, switches and programs to arbitrarily perform switching output signals, and the control part may be, for example, configured of a microcontroller, FPGA, CPLD, or other control circuits.

The first board 61 includes pins 619 which are a terminal for electrically connecting the first board 61 with another component. The second board 65 includes a socket 659 which is a connection part into/from which the pins 619 are capable of being inserted/removed. In the following descriptions, the pins 619 and the socket 659 are also referred to as “inter-board connectors 619 and 659”. In this embodiment, two boards are fitted and connected with each other through the inter-board connectors 619 and 659 and thus, the two boards are easily connected with each other and connection quality is also made uniform. Further, in this embodiment, the board is roughly divided into two boards based on types of input currents, functions and the like of parts mounted on the board and thus, the respective boards can be flexibly arranged at optimum positions. In addition, in the ice making device 90, lead wires are not used for connection of the first board 61 with the second board 65 and thus, a space for moderately loosening the lead wires is not required. As a result, structural efficiency of the ice making device 90 is enhanced.

Further, as shown in FIG. 5, the first board 61 and the second board 65 in this embodiment are perpendicularly connected with each other (so that respective face directions are intersected at an angle of 90°) by the inter-board connectors 619 and 659. When the first board 61 and the second board 65 are perpendicularly connected with each other, a maximum size in a three-dimensional direction after having been connected is smaller than a maximum size of the two boards which are connected on the same plane. As a result, the board is prevented from becoming a bottleneck for miniaturization.

As shown in FIG. 6, the first board 61 is mounted with, in addition to the

AC/DC converter 611, a mechanical relay 613 (hereinafter, simply referred to as a “relay 613”) for opening and closing a water supply valve which supplies water to the ice making tray 20. When the relay 613 having a mechanical contact is disposed on the first board 61, a problem such as noise and a spark is gathered to the first board 61. Further, although an operation of the relay 613 is controlled by the control device 651 on the second board 65, the second board 65 controls electric and electronic components by receiving supply of DC power from the first board 61 and thus, the second board 65 is arranged in an inner and back portion of the device with respect to the first board 61. Therefore, in this embodiment, the relay 613 which is connected with the water supply valve provided outside the device is disposed on the first board 61 instead of the second board 65 and thus, the relay 613 and the water supply valve are easily accessed. In addition, a varistor 612 is also mounted on the first board 61. When the first board 61 is provided with a detouring function of a surge current, a power supply function of the ice making device 90 is gathered on the first board 61. As a result, safety of the second board 65 is secured and a configuration of the second board 65 is simplified.

The second board 65 is connected with the motor 81, the above-mentioned main switch 655 and test switch 656, the thermistor 24 and the ice detection switch 71. Further, the second board 65 is mounted with a motor driver 652 which is a drive circuit for the motor 81.

The ice making device 90 uses a DC motor 81 as its drive source. When a DC motor is adopted as a drive source, drive and control of the motor, in other words, operation control of the ice making device 90 is easily performed. As a result, a wide variety of functions and operations of the ice making device 90 is realized by a simple configuration. In addition, the second board 65 is connected with the thermistor 24 and the ice detection switch 71 (whose specific functions are described below) and, as a result, parts relating to operation control of the ice making device 90 are gathered to the second board 65.

As described above, in the ice making device 90 in this embodiment, a function relating to a power supply is substantially gathered to the first board 61 and a function relating to operation control of the ice making device 90 is substantially gathered to the second board 65 and thus, the board is rationally and flexibly divided into two portions.

### Board Case and its Attaching Structure

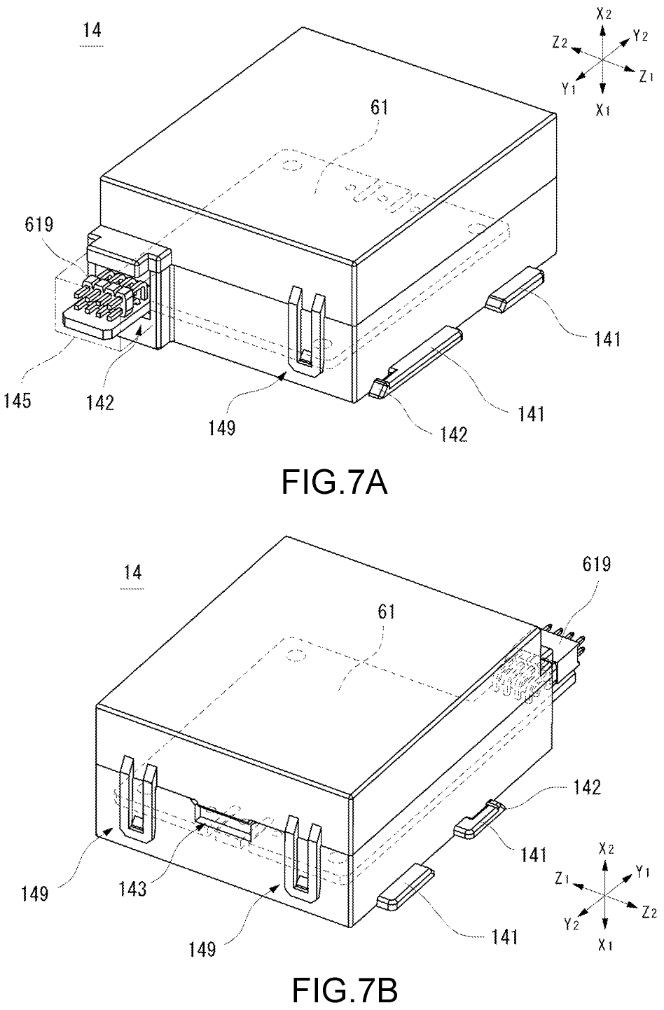

FIGS. 7A and 7B are perspective views showing an outward appearance of the board case 14. The board case 14 is a case body which accommodates the first board 61 in its inside. The first board 61 in this embodiment is first accommodated in the board case 14 and is assembled into an inside of the outer shell case 10 with the board case 14 as a unit.

As described above, the first board 61 is mounted with high power components such as the AC/DC converter 611 and the relay 613. In order to secure safety of the ice making device 90, the first board 61 is required to secure a sufficient insulation property and explosion-proof property. In the ice making device 90 in this embodiment, the first board 61 is accommodated in the board case 14. Therefore, securing of an insulation property and an explosion-proof property and conformity to a standard of safety can be flexibly and efficiently realized by using the board case 14. Further, assembling of the board case 14 to the ice making device 90 is easily performed by providing the board case 14 with various assembling structures (described below) and, as a result, connection quality of the inter-board connectors 619 and 659 can be made uniform and, further, the connecting state is firmly maintained.

As shown in FIGS. 7A and 7B, the board case 14 in this embodiment is a housing in a substantially rectangular parallelepiped shape. The board case 14 is assembled by joining a pair of half case bodies divided in the “X” direction (upper and lower direction in FIGS. 7A and 7B) with fitting type locks 149. The lock 149 in this embodiment is a lock structured of an elastic body in a tongue piece shape having a hole and a hook which is fitted to the hole and locks the elastic body.

A face on the “Y1” side of the board case 14 is provided with a terminal port 142 which is an opening for exposing the pins 619 outside. The pin 619 is a male terminal which is protruded outside from the board case 14. A face on the “Y2” side of the board case 14 is provided with a wiring port 143 which is an opening for passing a power line from a refrigerator. Further, each of faces on the “Z1” side and the “Z2” side of the board case 14 is provided with two slide plates 141 which are small pieces in a flat plate shape for attaching the board case 14 to the inner case 13. The slide plate 141 on the “Y1” side of each face is provided with a hook arm 142 which is an elastic arm having a hook extended to the “Y1” direction side. As described in detail below, the slide plate 141 structures a slide fitting part together with the slide guide 136 of the inner case 13, and the hook arm 142 structures a snap fitting structure together with a hook engaging part 136c of the slide guide 136.

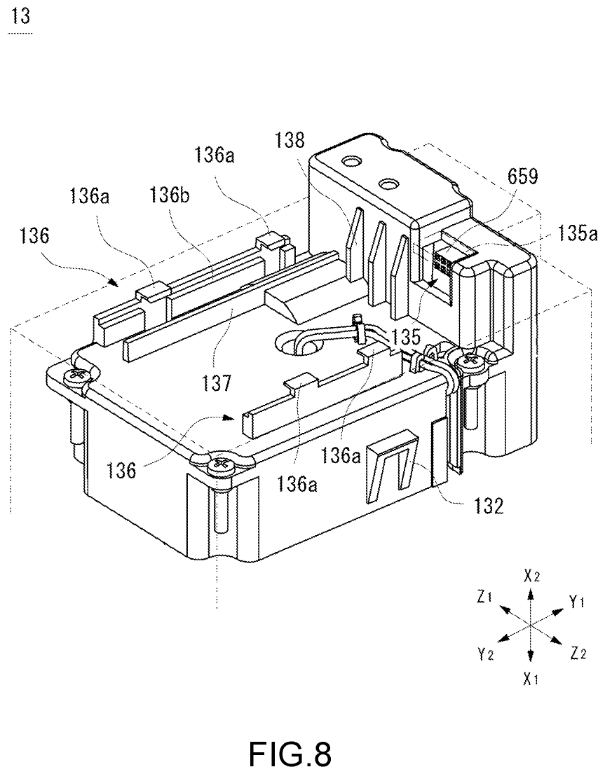

FIG. 8 is a perspective view showing a surface structure of the inner case 13. The inner case 13 in this embodiment is assembled with mechanical parts such as gears structuring the drive unit 91 and is also structured to be a case disposing part to which the board case 14 is attached.

The inner case 13 is provided with the slide guides 136 to which the above-mentioned four slide plates 141 are attached on its “X2” side face (upper face in FIG. 8). The slide guide 136 is provided at positions on the “Z1” side and the “Z2” side of the board case 14, in other words, two slide guides 136 are provided along the forming positions of the slide plates 141.

The slide guide 136 is provided with a hook-shaped pressing part 136a on which the slide plate 141 is slid and inserted, and a support base 136b on which the slide plate 141 is placed. Further, the inner case 13 in this embodiment is, in addition to the support base 136b of the slide guide 136, provided with a rail part 137 which supports a bottom face (face on the “X1” side) of the board case 14. The rail part 137 is a wall part which is linearly extended in the “Y” direction.

Further, the inner case 13 is provided with an insertion port 135 which is an opening for exposing the socket 659 of the second board 65 outside. In the ice making device 90 in this embodiment, the board case 14 is attached to the inner case 13 and thereby, the pins 619 of the first board 61 are inserted into the socket 659 of the second board 65. In the ice making device 90 in this embodiment, as also described above, the first board 61 and the second board 65 are connected with each other through a connector capable of being inserted/removed instead of soldering of lead wires and thus, connection work between the boards is easily performed and constant connection quality can be attained regardless of working skill of an operator. In this embodiment, the first board 61 is provided with the pins 619 and the second board 65 is provided with the socket 659. However, the male and female terminals may be reversed.

Further, the inner case 13 is provided on the “Y1” side with respect to the slide guide 136 with a stopper part 138 with which the “Y1” side face of the board case 14, i.e., a face of the board case 14 on an inserting direction side of the pins 619 is abutted. The stopper part 138 in this embodiment is formed on a wall face which faces the “Y1” side face of the board case 14, and a plurality of ribs linearly extended in the “X” direction is arranged in the “Z” direction.

Further, the insertion port 135 in this embodiment is formed in a shape that its opening is enlarged toward the “X2” side so that an operator is capable of visually recognizing the socket 659. As a result, an operator is capable of connecting the pins 619 with the socket 659 while visually observing them directly. In this embodiment, a normal assembling procedure is that the board case 14 is slid along the slide guide 136 and the pins 619 are inserted into the socket 659. On the other hand, since the socket 659 can be seen by an operator, there is a risk that the operator directly inserts the pins 619 into the socket 659 in a wrong direction instead of sliding the board case 14 determined in the normal procedure. In order to prevent this problem, it may be structured that the socket 659 is covered by a blindfold part 135a so that the socket 659 cannot be seen in a direction other than the inserting direction of the pins 619, in other words, the socket 659 cannot be seen from the operator. According to this structure, the work error can be prevented. In addition, it may be conceivable that the board case 14 is provided with a terminal housing 145 (see FIG. 7A) in a tube shape which surrounds the pins 619. When such a terminal housing 145 is provided, an inserting direction of the pins 619 can be set in a normal direction.

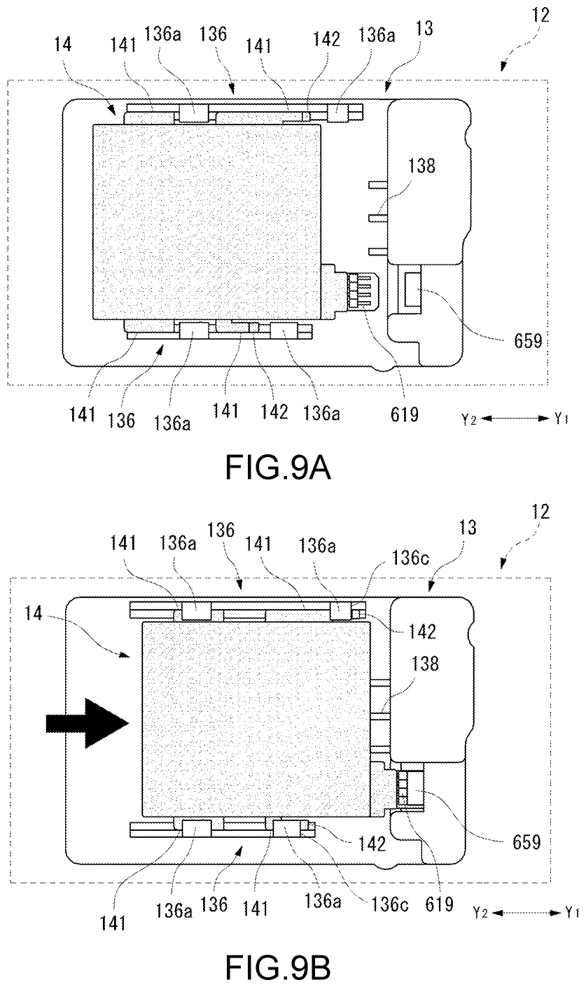

FIGS. 9A and 9B are schematic views showing an attaching method of the board case 14 to the inner case 13. Functions and effects of various assembling structures provided in the board case 14 and the inner case 13 will be described below with reference to FIGS. 9A and 9B. In FIGS. 9A and 9B, the board case 14 is colored so that respective members are easily distinguished.

When the board case 14 is to be attached to the inner case 13, first, as shown in FIG. 9A, the board case 14 is placed on the slide guide 136 so that the respective slide plates 141 of the board case 14 are disposed on the “Y2” side with respect to the respective pressing parts 136a.

Next, as shown in FIG. 9B, the board case 14 is slid to the “Y1” direction side, in other words, in the inserting direction of the pins 619 along the slide guides 136, and the respective slide plates 141 are inserted to the pressing parts 136a. When the board case 14 is slid to the “Y1” direction side by a predetermined amount, the pins 619 of the first board 61 are inserted into the socket 659. Further, the slide plates 141 and the pressing parts 136a are fitted to each other and thereby, the board case 14 is prevented from moving except the inserting/removing direction of the pins 619. As described above, in this embodiment, insertion of the pins 619 and fixing of the board case 14 are simultaneously performed only by a sliding operation of the board case 14 and thus, assemblability of the ice making device 90 is enhanced.

Further, in this case, a hook portion of each of the two hook arms 142 of the slide plates 141 is contacted with the pressing part 136a when the hook portion is to be passed through the pressing part 136a and thus, the hook arm 142 is elastically deformed so that the hook portion is moved downward under the pressing part 136a. Next, when the hook portion is passed through the pressing part 136a, the hook arm 142 returns to its original shape and the hook portion is engaged with the hook engaging part 136c which is the “Y1” side face of the pressing part 136a. As a result, movement of the board case 14 to the “Y2” direction side, in other words, movement of the pin 619 in a pulling-out direction is prevented. Further, insertion of the predetermined amount of the pin 619 is transmitted to an operator through a returned sound of the hook arm 142 or its feeling and thus, an insertion state of the pin 619 is made uniform and connection quality between the first board 61 and the second board 65 is stable.

Further, in this case, the “Y1” side face of the board case 14, i.e., the face of the board case 14 on the inserting direction side of the pin 619 is abutted (or substantially abutted) with the stopper part 138 of the inner case 13, and further movement to the “Y1” direction side of the board case 14 is prevented by the stopper part 138. As a result, excessive insertion of the pin 619 is prevented.

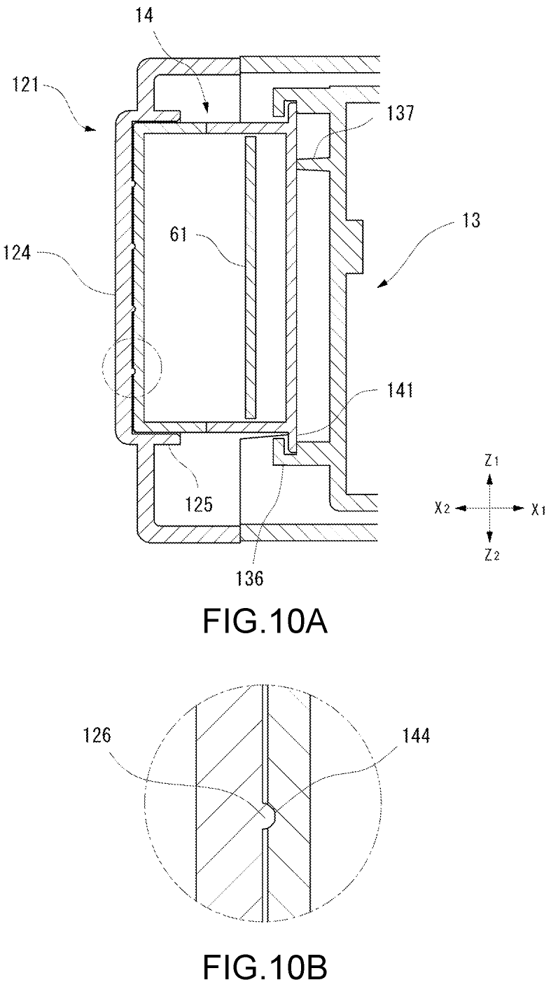

FIG. 10A is a schematic cross-sectional view showing a fixing structure of the board case 14 by the cover part 121. FIG. 10B is an enlarged view showing a portion surrounded by the alternate long and short dash line in FIG. 10A. An inner face of the cover part 121 in this embodiment is contacted with an opposing face (“X2” side face) of the board case 14. Further, the inner face of the cover part 121 is formed with a recessed part 124 whose shape is the same as a shape of the opposing face of the board case 14 (an outer face of the cover part 121 is formed with a corresponding protruded part). The board case 14 is pressed by the cover part 121 and, in addition, the board case 14 is fitted to the recessed part 124. Therefore, the board case 14 is prevented from moving in any direction, and a firm connection of the first board 61 with the second board 65 is maintained. In addition, the inner face of the cover part 121 in this embodiment is also formed with a rib 125 to which a periphery of the opposing face of the board case 14 is fitted. The above-mentioned effect of the recessed part 124 can be also obtained by the rib 125. In this embodiment, the cover part 121 is provided with both of the recessed part 124 and the rib 125 and thus, fixed effect of the board case 14 by the cover part 121 is increased.

In addition, when the recessed part 124 and the rib 125 of the cover part 121 are not properly fitted to the board case 14, an operator is capable of recognizing insufficient insertion of the pin 619.

Further, in this embodiment, the inner face of the cover part 121 and the opposing face of the board case 14 are provided with protruded parts 126 and recessed parts 144 whose shapes are paired. When the cover part 121 is attached to the board case 14, the recessed parts 144 and the protruded parts 126 are fitted to each other. The fixed effect of the board case 14 is also enhanced by fitting the protrusion to the recess. The protrusions and recesses may be those linearly extended in any direction or in a plurality of directions, or the protrusions and recesses may be scattered.

### Detail of Drive Mechanism

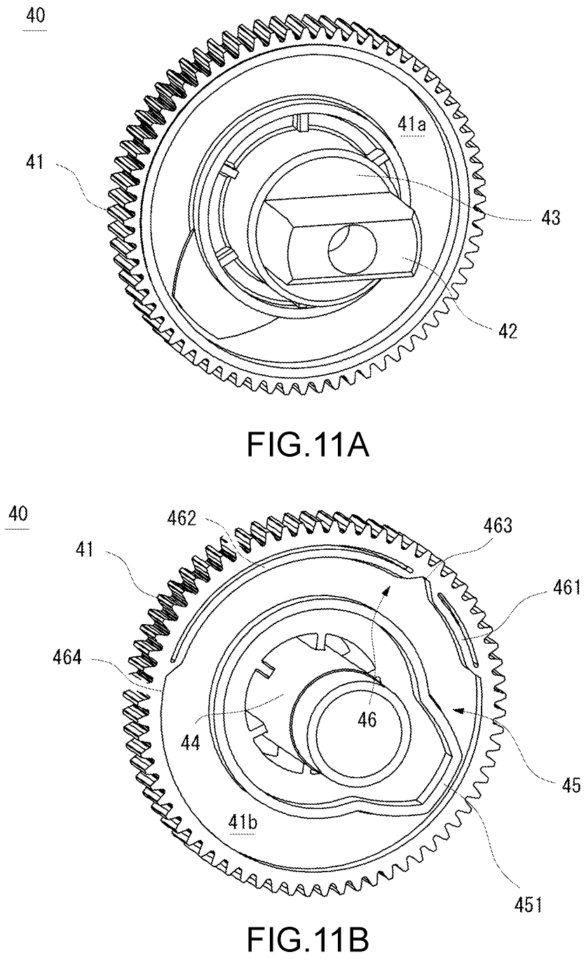

Details of respective parts which structure a drive mechanism of the drive unit 91 will be described below with reference to FIGS. 11A through 13B.

FIGS. 11A and 11B are perspective views showing a structure of the cam gear 40. FIG. 11A is a perspective front view showing a front face side of the cam gear 40, and FIG. 11B is a perspective rear view showing a rear face side of the cam gear 40. As shown in FIG. 11A, the cam gear 40 is provided on its front face 41a side with an ice making tray fitting shaft 42, which is a shaft part in a rectangular shape that is connected with a rear end part of the ice making tray 20, and a case fitted shaft 43 which is a circular shaft part that is supported by a bearing not shown provided in the outer shell case 10.

As shown in FIG. 11B, a rear face 41b side of the cam gear 40 is provided with a tube part 44 in a cylindrical tube shape at its center. A lowering stopping sleeve 49 described below is attached to an outer face of the tube part 44. The rear face 41b of the gear part 41 is formed with a first cam 45 and a second cam 46 which are ribs structuring a driver part of a plane cam mechanism. The first cam 45 is a rib formed in a substantially circular ring shape. The driven shaft 50 is turned along a shape of an inner peripheral face of the first cam 45. The first cam 45 is provided with a recessed slope 451 which is a slope stretched to an outer side in a radial direction in a predetermined range in a circumferential direction. The second cam 46 is a rib which is formed along a periphery on the rear face 41b side of the gear part 41. The switch lever 72 is turned along a shape of an inner peripheral face of the second cam 46. The second cam 46 is provided with a former side protruded slope 461 and a latter side protruded slope 462 which are slopes on which the switch lever 72 rides, an intermediate recessed slope 463 which is a downward slope provided between the protruded slopes 461 and 462, and a terminal recessed slope 464 which is a downward slope continuing in a clockwise direction from the latter side protruded slope 462.

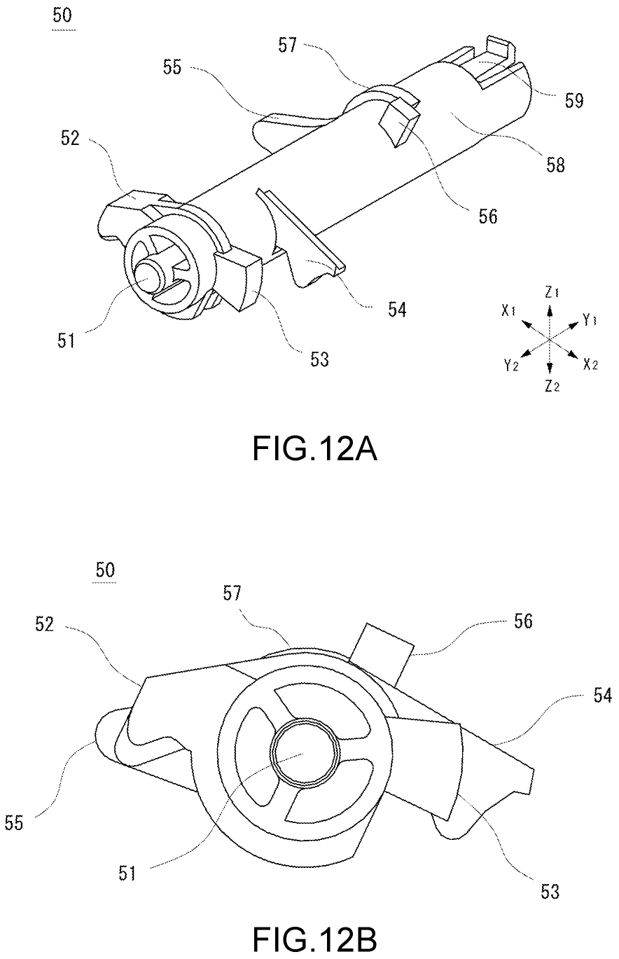

FIG. 12A is a perspective view showing a structure of the driven shaft 50 and FIG. 12B is its side view. The driven shaft 50 is provided with a tip end shaft 51 and an intermediate shaft 58 which are shaft parts supported by the box part 12 including the inner case 13. The driven shaft 50 is provided with a plurality of protruded parts on a body part in a columnar shape. These protruded parts are structured, from the “Y2” side toward the “Y1” side, of a sliding part 52 which is a cam follower contacting with the first cam 45, a turning stopping part 53 which is abutted with the lowering stopping sleeve 49 described below to prevent turning of the driven shaft 50 in the “CCW” direction in FIG. 12B, a spring receiving part 54 which is always urged toward an upper side (in other words, so as to turn the driven shaft 50 in the “CCW” direction) by a coil spring 541 (see FIG. 3), a first positioning piece 55 which is inserted into a recessed part not shown of the box part 12 to restrict a turning range of the driven shaft 50, a switch lever operation part 56 which is contacted with the switch lever 72 to operate a swing angle of the switch lever 72, and a second positioning piece 57 which is contacted with an inner face of the box part 12 to prevent movement of the driven shaft 50 in the “Y1” direction.

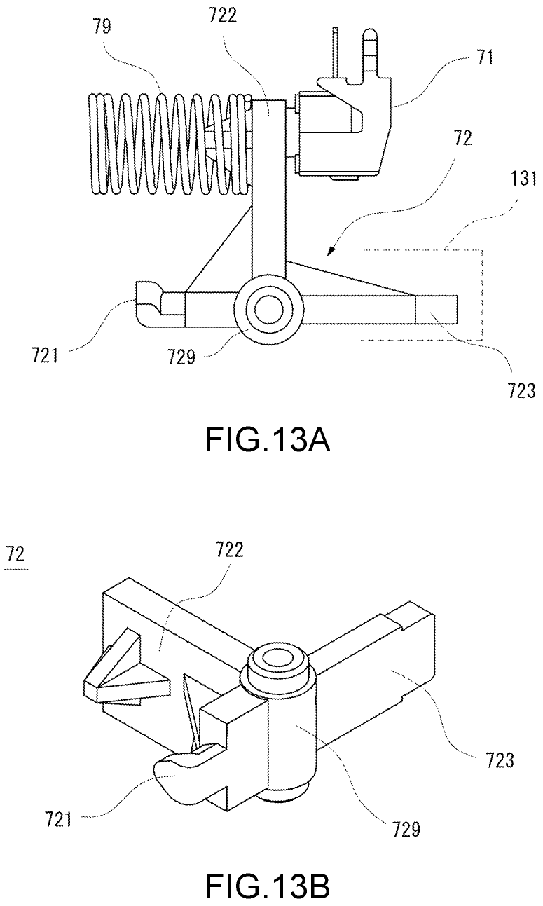

FIG. 13A is a plan view showing a structure of the switch lever 72 and FIG. 13B is its perspective view. The switch lever 72 is an arm-shaped member having a shaft part 729 which is a turning center, and a plurality of free ends which are turned with the shaft part 729 as a turning center. The switch lever 72 is, as the free end, provided with a sliding part 721 which is a cam follower contacting with the second cam 46, a switch operation part 722 which is always urged to a side of the ice detection switch 71 by a coil spring 79, and a turning restriction part 723 which is inserted into a recessed part 131 of the inner case 13 to restrict a turning range of the switch lever 72.

### Detail of Ice Separating Operation

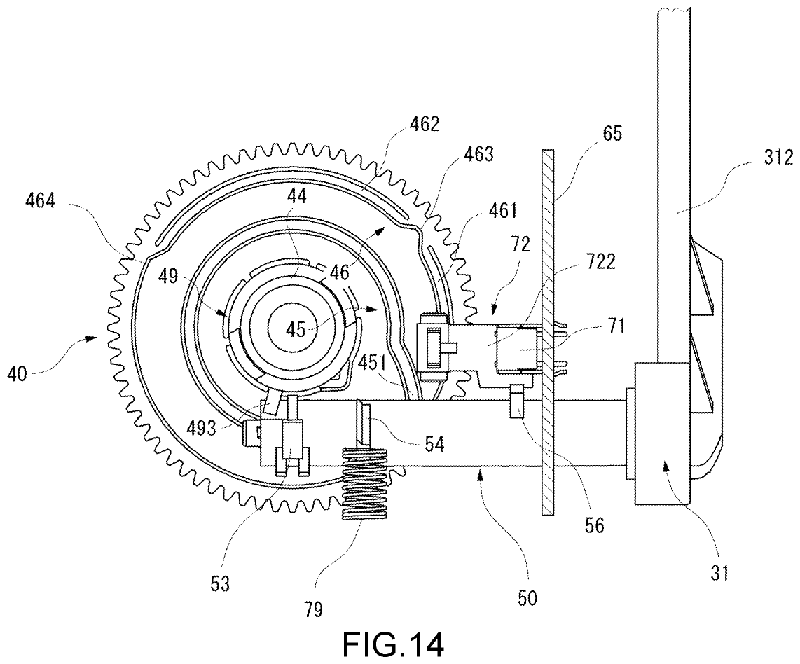

The ice separating operation of the ice making device 90 will be described further in detail below with reference to FIGS. 14 through 18.

FIG. 14 is a rear view showing the drive mechanism when the ice making tray 20 is located at an ice making position. In this case, the sliding part 52 of the driven shaft 50 is located outside the recessed slope 451 of the first cam 45 and thereby, the ice detection lever 31 is raised upward. The sliding part 721 of the switch lever 72 does not ride on the former side protruded slope 461 yet and thus, the ice detection switch 71 is set in an “ON” state.

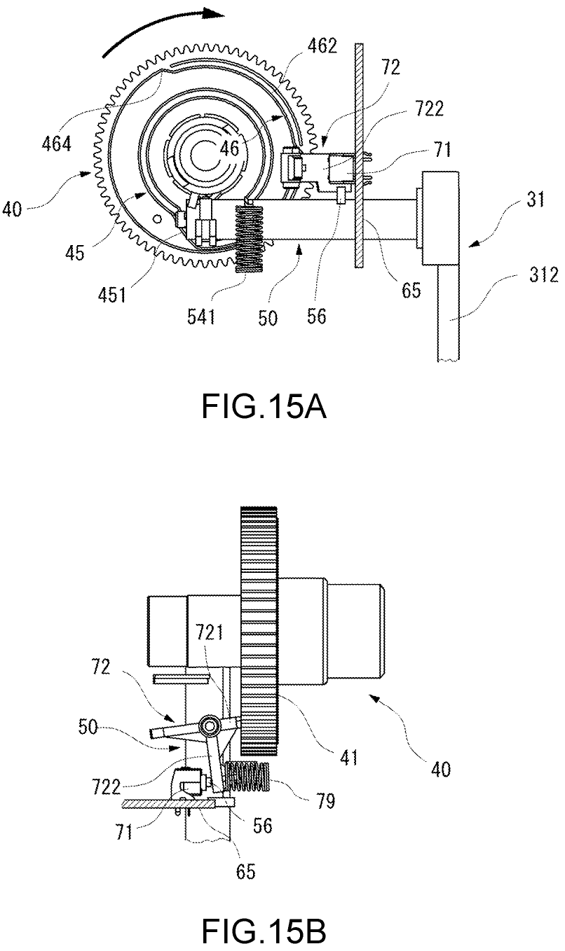

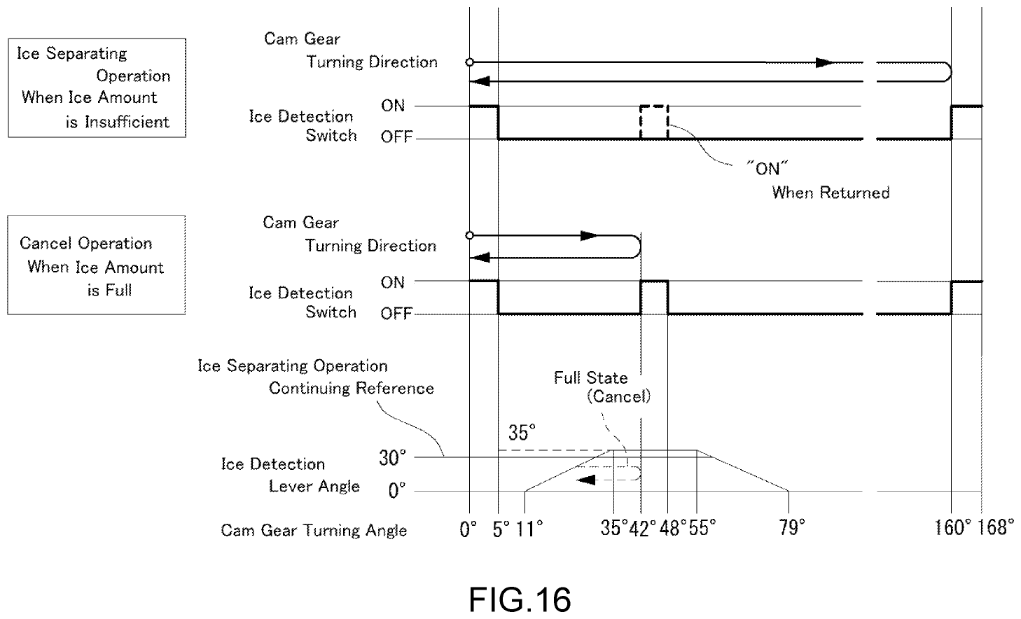

FIG. 15A is a rear view showing the drive mechanism when an ice detection operation is performed and FIG. 15B is its side view. FIG. 16 is a timing chart showing operations of respective parts when an ice separating operation is continued and canceled. When an ice separation preparatory operation has completed, the drive unit 91 turns the cam gear 40 in the “CW” direction in the drawing. As a result, the sliding part 52 of the driven shaft 50 enters the recessed slope 451 and the ice detection lever 31 is lowered. When the ice detection lever 31 starts to be lowered, the sliding part 721 of the switch lever 72 simultaneously rides on the former side protruded slope 461 and the ice detection switch 71 is switched to an “OFF” state.

When lowering of the ice detection lever 31 is not prevented by ice pieces and the arm part 312 is turned 30° or more and, when the lifting and lowering part 313 is lowered exceeding a reference level within an inside of the ice storage part 92, in other words, when the sliding part 52 of the driven shaft 50 has reached a deep part of the recessed slope 451, the switch lever operation part 56 of the driven shaft 50 is contacted with the switch operation part 722 of the switch lever 72 to press the switch operation part 722 in a direction separated from the ice detection switch 71. When the cam gear 40 is turned to a position where the sliding part 52 of the driven shaft 50 is located at the deep part of the recessed slope 451, the sliding part 721 of the switch lever 72 reaches a position of the intermediate recessed slope 463 of the second cam 46. In this case, when the ice detection lever 31 has been sufficiently lowered and a return of the switch operation part 722 of the switch lever 72 (return to the ice detection switch 71 side) is restricted by the switch lever operation part 56 of the driven shaft 50, the ice detection switch 71 is kept in the “OFF” state and the cam gear 40 continues turning in the “CW” direction.

In this embodiment, when lowering of the ice detection lever 31 is prevented by stored ice pieces and the driven shaft 50 is not turned sufficiently, the switch lever operation part 56 of the driven shaft 50 does not reach the switch operation part 722 of the switch lever 72 and, as a result, the sliding part 721 of the switch lever 72 is moved along the intermediate recessed slope 463 to switch the ice detection switch 71 to an “ON” state. When the control device of the refrigerator detects that the ice detection switch 71 has been switched to the “ON” state within a predetermined time period, the control device cancels the ice separating operation and returns the ice making tray 20 to the ice making position without discharging ice pieces.

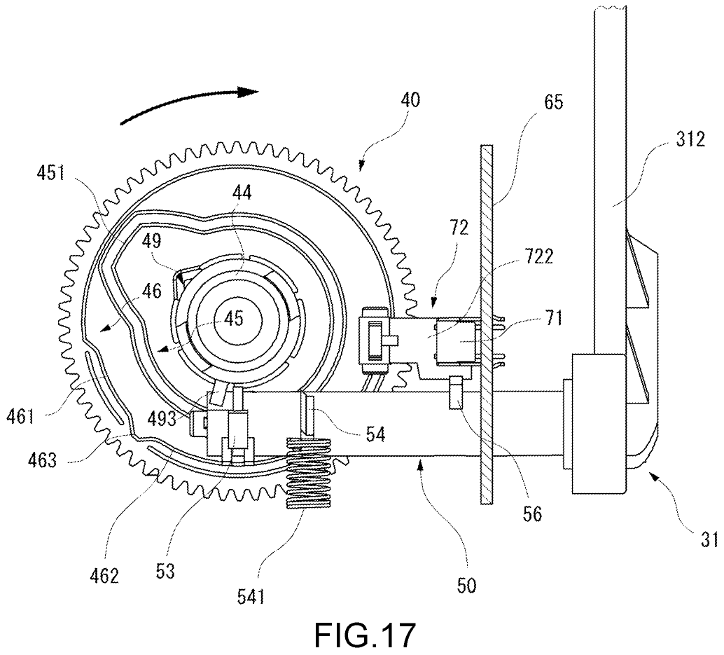

FIG. 17 is a rear view showing the drive mechanism at the time of a discharge operation of ice pieces. When the intermediate recessed slope 463 has been passed while the ice detection switch 71 is kept in an “OFF” state, the sliding part 52 of the driven shaft 50 rides on the opposite side cam with respect to the recessed slope 451 and thereby, the ice detection lever 31 is lifted up. In this case, the sliding part 721 of the switch lever 72 has ridden on the latter side protruded slope 462 and thus, even when the switch lever operation part 56 of the driven shaft 50 does not press down the switch operation part 722 of the switch lever 72, the ice detection switch 71 is kept in the “OFF” state. When the ice making tray 20 has been fully twisted in the “CW” direction in the drawing and ice pieces has been discharged, the sliding part 721 of the switch lever 72 is lowered to the terminal recessed slope 464 and the ice detection switch 71 is switched to an “ON” state. The refrigerator detects completion of discharge of ice pieces based on the switching of the ice detection switch 71.

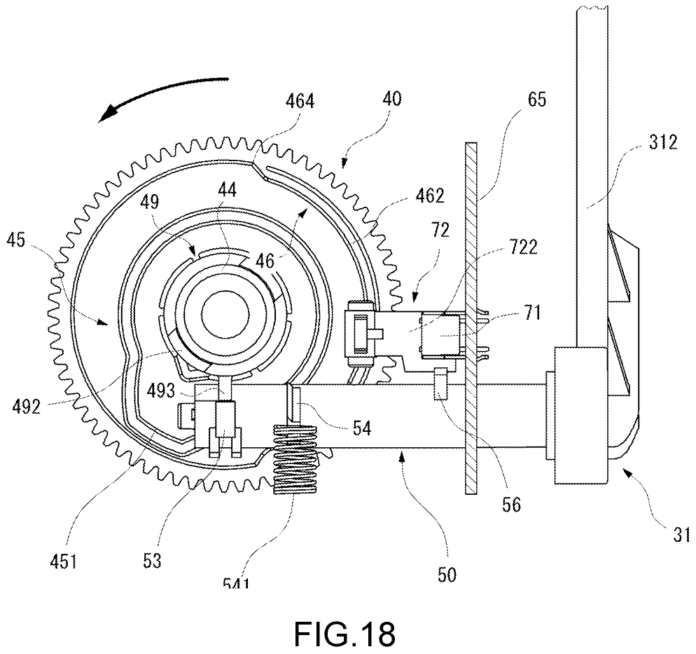

FIG. 18 is a rear view showing the drive mechanism after ice pieces have been discharged. When discharge of ice pieces has been finished, the ice making device 90 returns the ice making tray 20 to the ice making position. In this embodiment, the tube part 44 of the cam gear 40 is attached with the lowering stopping sleeve 49 in a cylindrical tube shape. The lowering stopping sleeve 49 is provided with a body part formed with a slit 492 and a protruded part 493 which is protruded to an outer side from the body part. The lowering stopping sleeve 49 is not fixed to the tube part 44 and is turned with the tube part 44 by frictional resistance. A turning range of the protruded part 493 is restricted by the case body 11, and the protruded part 493 is reciprocated within the movable range in the turning direction of the cam gear 40. After ice pieces have been discharged, when the cam gear 40 is turned in the “CCW” direction in the drawing, the sliding part 52 of the driven shaft 50 is moved to the recessed slope 451 again. However, in this case, the turning stopping part 53 of the driven shaft 50 is abutted with the protruded part 493 of the lowering stopping sleeve 49 and the driven shaft 50 is prevented from being turned. Therefore, the ice detection lever 31 does not go down during the return operation.

Embodiments of the present invention may be structured as follows.
(1) An ice making device having an ice making tray, the ice making device including an outer shell case which is a case body structuring an outer shape of the device and a board case which accommodates a circuit board, and the board case is disposed in an inside of the outer shell case.
(2) The ice making device described in the above-mentioned structure (1), where the circuit board includes a terminal which electrically connects the circuit board with another component, the board case is provided with a terminal port which is an opening for exposing the terminal outside, the terminal is a male terminal or a female terminal which is capable of being inserted to and removed from a connection part of the another component, an inside of the outer shell case is provided with a case disposing part to which the board case is attached, and the terminal of the circuit board is connected with the connection part of the another component by attaching the board case to the case disposing part.
(3) The ice making device described in the above-mentioned structure (2), where the board case and the case disposing part are respectively provided with slide fitting parts, the slide fitting parts are fitted to each other by sliding the board case on the case disposing part in an insertion direction of the terminal, and the board case is prevented from moving except an inserting and removing direction of the terminal.
(4) The ice making device described in the above-mentioned structure (2) or (3), where the case disposing part is provided with a stopper part, and the stopper part is abutted with the board case when the board case is slid in an insertion direction of the terminal on the case disposing part to determine a moving limit in the insertion direction of the board case.
(5) The ice making device described in one of the above-mentioned structures (2) through (4), where the board case and the case disposing part are respectively provided with snap-fit structures, and the snap-fit structures are fitted to each other by sliding the board case in an insertion direction of the terminal on the case disposing part.
(6) The ice making device described in one of the above-mentioned structures (2) through (5), where the outer shell case includes a cover part which can be attached and detached, an inner face of the cover part is contacted with an opposing face which is an outer face of the board case, and the inner face of the cover part is formed with a recessed part whose shape is same as a shape of the opposing face of the board case with which the cover part is contacted, or formed with a rib which is fitted to a periphery of the opposing face of the board case.
(7) The ice making device described in the above-mentioned structure (6), where the inner face of the cover part and the opposing face of the board case are provided with a protrusion and a recess whose shapes are paired, and the protrusion and the recess are fitted to each other by attaching the cover part.
(8) The ice making device described in the above-mentioned structure (1), where the case disposing part is provided with an insertion port which is an opening into which the terminal is inserted, a connection part of another component is disposed on a rear side with respect to the insertion port, and the connection part is invisible in a direction other than an insertion direction of the terminal.
(9) The ice making device described in the above-mentioned structure (8), where the board case is provided with a terminal housing which surrounds the terminal in a tube shape.
(10) The ice making device described in one of the above-mentioned structures (1) through (9), further including a first board which is the circuit board having a converter which converts an alternating current (AC) to a direct current (DC), and a second board which is another component with which a part operated by the DC is connected, where the second board has a control part which controls an operation of the ice making device, and the terminal of the first board is connected with the second board through an inter-board connector which is a connection part.
(11) The ice making device described in the above-mentioned structure (10), where the inter-board connector perpendicularly connects the first board with the second board.
(12) The ice making device described in the above-mentioned structure (10) or (11), where no lead wire is used for connection of the first board with the second board.
(13) The ice making device described in one of the above-mentioned structures (10) through (12), where the first board has a relay which opens and closes a water supply valve for supplying water to the ice making tray.
(14) The ice making device described in one of the above-mentioned structures (10) through (13), where the first board has a varistor.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. An ice making device comprising:
an ice making tray;
an outer shell case which is a case body structuring an outer shape of the device; and
a board case which accommodates a circuit board;
wherein the board case is disposed in an inside of the outer shell case.

2. The ice making device according to claim 1, wherein
the circuit board comprises a terminal which electrically connects the circuit board with another component,
the board case is provided with a terminal port which is an opening for exposing the terminal outside,
the terminal is a male terminal or a female terminal which is capable of being inserted to and removed from a connection part of the another component,
an inside of the outer shell case comprises a case disposing part to which the board case is attached, and
the terminal of the circuit board is connected with the connection part of the another component by attaching the board case to the case disposing part.

3. The ice making device according to claim 2, wherein
the board case and the case disposing part respectively comprise slide fitting parts,
the slide fitting parts are fitted to each other by sliding the board case on the case disposing part in an insertion direction of the terminal, and
the board case is prevented from moving except an inserting and removing direction of the terminal.

4. The ice making device according to claim 2, wherein
the case disposing part comprises a stopper part, and
the stopper part is abutted with the board case when the board case is slid on the case disposing part in an insertion direction of the terminal to determine a moving limit of the board case in the insertion direction.

5. The ice making device according to claim 2, wherein
the board case and the case disposing part respectively comprise snap-fit structures, and
the snap-fit structures are fitted to each other by sliding the board case on the case disposing part in an insertion direction of the terminal.

6. The ice making device according to claim 2, wherein
the outer shell case comprises a cover part which is capable of being attached and detached,
an inner face of the cover part is contacted with an opposing face which is an outer face of the board case, and
the inner face of the cover part is formed with:
a recessed part whose shape is same as a shape of the opposing face of the board case with which the cover part is contacted; or
a rib which is fitted to a periphery of the opposing face of the board case.

7. The ice making device according to claim 6, wherein
the inner face of the cover part and the opposing face of the board case are provided with a protrusion and a recess whose shapes are paired, and
the protrusion and the recess are fitted to each other by attaching the cover part to the board case.

8. The ice making device according to claim 2, wherein
the case disposing part is provided with an insertion port which is an opening into which the terminal is inserted,
the connection part of the another component is disposed on a rear side with respect to the insertion port, and
the connection part is invisible in a direction other than an insertion direction of the terminal.

9. The ice making device according to claim 8, wherein the board case comprises a terminal housing which surrounds the terminal in a tube shape.

10. The ice making device according to claim 2, further comprising:
a first board which is the circuit board comprising a converter which converts an alternating current to a direct current, and
a second board which is the another component with which a part operated by the direct current is connected,
wherein the second board comprises a control part which controls an operation of the ice making device, and
the terminal of the first board is connected with the second board through an inter-board connector which is the connection part.

11. The ice making device according to claim 10, wherein the inter-board connector perpendicularly connects the first board with the second board.

12. The ice making device according to claim 10, wherein no lead wire is used for connection of the first board with the second board.

13. The ice making device according to claim 10, wherein the first board comprises a relay which opens and closes a water supply valve for supplying water to the ice making tray.

14. The ice making device according to claim 10, wherein the first board comprises a varistor.
